(19) United States
(12) Patent Application Publication
(10) Pub. No.: US 2020/0031718 A1
(43) Pub. Date: Jan. 30, 2020

(54) CONSTRUCTION MATERIAL MIXTURE FOR SHIELDING AGAINST ELECTROMAGNETIC RADIATION

(71) Applicant: HEKA graphit.technology GmbH, Ludwigslust (DE)

(72) Inventor: Jens Düwel, Ludwigslust (DE)

(73) Assignee: HEKA graphit.technology GmbH, Ludwigslust (DE)

(21) Appl. No.: 16/477,302

(22) PCT Filed: Jan. 15, 2018
(86) PCT No.: PCT/EP2018/050910

§ 371 Date: Jul. 11, 2019

(30) Foreign Application Priority Data
Jan. 14, 2017 (DE) 10 2017 000 236.3

(51) Int. Cl. C04B 28/16; C04B 28/12; C04B 14/02; C04B 14/30; C04B 20/10; C04B 14/34; C04B 24/26; C04B 24/42; H05K 9/00

(52) U.S. Cl. CPC C04B 28/16; C04B 28/12; C04B 14/024; C04B 14/308; C04B 2111/94; C04B 14/34; C04B 24/2641; C04B 24/42; H05K 9/0083; C04B 20/1055

(57) ABSTRACT

A construction material mixture contains a dry mass of 10 to 98 wt. % carbon and 2 to 70 wt. % binding agent. The construction material mixture further comprises 1 to 80 wt. % loose particles, wherein the surface of the loose particles is at least partially coated with an electrically conductive material.

The present invention relates to a construction material mixture for shielding against electromagnetic radiation, for instance a construction material mixture that can be implemented as a plaster compound or as a base material for the manufacture of construction elements, in particular of dry construction elements.

The growing digital interconnectedness of all areas in work and life, as well as the expansion of wireless communication and data transmission leads to an ever greater increase in electromagnetic radiation, in particular in high-frequency areas, which is referred to as so-called “electrosmog”. This electrosmog is not only a problem in terms of worker protection and health, but rather the overlapping electromagnetic fields also constitute a technical problem—in particular in terms of security—for industry, administration and security-related facilities in many areas. Known shielding solutions against electromagnetic radiation are based on the reflection of electromagnetic radiation, which, although minimizing the electromagnetic radiation penetrating the space that is shielded accordingly, does not essentially reduce the same as the radiation is ultimately merely reflected into other areas.

In the international patent application WO 2016/087673 A1 of the applicant, a construction material mixture containing graphite is described, which, due to its high thermal conductivity, can be used in the form of a filler or plaster compound for surface heating systems or the like. Due to their high electric conductivity, the filler compounds manufactured from the known construction material compounds are also characterized by a high reflective capability for electromagnetic waves, in particular high-frequency electromagnetic waves, such as e.g. mobile radio radiation or radar radiation. This filler compound is also not able to minimize impinging electromagnetic radiation in an effective manner.

The technical problem underlying the present invention is thus to indicate a construction material mixture of the type described above, which not only reflects electromagnetic radiation, in particular high-frequency electromagnetic radiation, but for the most part absorbs the same so that the electromagnetic radiation is not only prevented from passing through barriers, but is considerably reduced overall.

The construction material mixture can be used for instance as a plaster compound. In particular, the plaster compound in a set state should exhibit extremely high electromagnetic shielding predominantly by absorption. The aim is to convert the radiation into heat within the material thickness in the shield and thus to eliminate the same. Radiation shielding by reflection should be reduced to the greatest possible extent and even avoided entirely. The plaster compound should continue to exhibit a very high thermal conductivity in order to support surface heating systems. It should be possible to paint over, wallpaper or cover the hardened construction material mixture with tiles and other construction materials. It should be possible to apply the construction material mixture to the surface to be covered by hand or by machine. It should also be possible to inject/cast the construction material into moulds and process the same via a 3D printer.

This technical problem is solved by a construction material mixture with the features of the present claim 1. The dependent claims are directed to advantageous embodiments of the construction material mixture in accordance with the invention.

The invention is thus directed to a construction material mixture, the dry mass of which comprises 10 to 98 wt % carbon and 2 to 70 wt % binding agent, wherein the construction material mixture in accordance with the invention is characterized in that the construction material mixture further comprises 1 to 80 wt % loose particles, wherein the surface of the loose particles is at least partially coated with an electrically conductive material.

When components of the construction material mixture are indicated in the present description, it is self-explanatory that only such combinations of components are comprised the sum of whose components, apart from impurities caused by manufacturing conditions, yield 100 wt %. The parts of the components are always to be understood as relating to the dry mass, i.e. without mixing liquids such as, e.g., water.

The concentrations of the components of the construction material mixture in accordance with the invention comprise all values explicitly designated, but also all values falling within the claimed ranges that are not explicitly designated.

As an example, the upper limit of the percentage interval for carbon is 98, 95, 90, 85 or 80 wt (%). The following values hold, for example, for the lower limit: 20, 25, 30, 35, 40, 45, 50 wt (%). The disclosure of this application also comprises the set of all intervals that are defined by all possible combinations of the aforementioned upper and lower limits.

Furthermore, the upper limit of the percentage interval for binding agent is, e.g., 70, 65, 60, 55, 50 or 45 wt (%). The following values are possible, for example, as the lower limit: 2, 4, 7, 10, 15, 20, 25, 30, 35 or 40 wt (%). The disclosure of this application in turn comprises the set of all intervals that are defined by all possible consistent combinations of the aforementioned upper and lower limits.

The loose particles coated with an electrically conductive material induce multiple reflections of the electromagnetic radiation penetrating the construction material mixture so that the bulk of the electromagnetic radiation in the construction material mixture can be absorbed, which reduces the reflected or transmitted part of the electromagnetic radiation.

By means of the adjustment/modification of the concentrations of the individual components, in particular of the bulk part of carbon and of the part of electrically conductive coating, the absorption and reflection properties can be modified in broad ranges and adapted to the respectively desired properties of the end products.

The coating of the loose particles can occur during the manufacturing of the construction material mixture, for instance uncoated loose particles of the construction material mixture can adsorb a portion of the carbon contained in the construction material mixture in the form of a surface coating.

According to a preferred embodiment of the invention, however, the construction material mixture contains loose particles pre-coated with the electrically conductive material. “Pre-coated loose particles” in the present context are understood to be particles for which an electrically conductive material is applied to the particle surface before their addition to the construction material mixture. Preferably, an adhesive agent, for instance a glue, is used in this case in order to improve the adhesion of the electrically conductive material to the particle surface.

In one embodiment, the surface of the loose particles can be completely coated with electrically conductive material. The use of loose particles whose surface is not completely coated with electrically conductive material, however, is particularly preferred. In this case, the coated part of the surface of the loose particles is advantageously on average between 50 and 90%. In this embodiment, the degree of absorption for electromagnetic radiation is further improved, because electromagnetic radiation can enter the particles in the uncoated areas and is reflected repeatedly on the adjacent coated surfaces, which increases the absorption of the radiation within the particles.

The loose particles can consist of a great variety of materials; preferably, however, the particles are made of glass or ceramic materials.

The geometry of the loose particles is also not subject to any restriction whatsoever. However, with a view to a particularly effective absorption, the loose particles are preferably spheres, in particular hollow spheres, for instance hollow spheres of glass, such as for instance glass microspheres (glass microbubbles). Potentially suitable loose particles are, for instance, the expanded glass granule sold in a great variety of sizes and size distributions by the company Dennert Poraver GmbH, Postbauer-Heng, Germany, under the product name “Poraver”.

The size of the loose particles, i.e. for instance the diameter of the sphere in the case of spheres, preferably lies in the range of 0.01 mm to 10 mm.

The volume percentage of the coated loose particles, for instance of the coated spheres in the construction material mixture, can be high and for instance more than 50 vol. % or even more than 75 vol. %.

According to an embodiment, the carbon of the dry compound comprises graphite, i.e. the carbon of the dry compound is made up of graphite.

According to a further embodiment of the construction material mixture in accordance with the invention, the electrically conductive material is selected from the group consisting of magnetite (Fe₃O₄), graphite and graphene or combinations of these materials.

Magnetite is already used in the construction industry as a naturally granular additive with a high bulk density (4.65 to 4.80 kg/dm³) for lime sand bricks and heavy concrete and for radiation protection in the field of construction. Therefore, in the present context, magnetite can be used not only as a coating for the loose particles, but also as an additive for the construction material mixture.

Preferably, however, a carbon-based coating such as graphite or graphene is used, i.e., in preferred embodiments of the construction material mixture in accordance with the invention, carbon is found both in the bulk material as well as in the coating.

The graphite as a component of the dry compound or the graphite as a coating of the loose particles can be present as a graphite powder, as expanded graphite flakes, as film graphite, natural graphite or synthetic graphite. The invention can be realized with a multitude of different variants of graphite, which is a testament to the flexibility of the invention. The list described here is not exhaustive, but rather only illustrative.

The loose particles are particularly preferably coated with graphene. Graphene is a modification of the carbon with a two-dimensional structure, wherein every carbon atom is surrounded by three further carbon atoms at an angle of 120° so that, analogous to the layers of graphite, a honeycomb-shaped carbon structure is formed. Unlike graphite, however, graphene consists of a single layer of carbon and is characterized by a particularly high mechanical stability in the plane, as well as a high electric conductivity in this plane.

A great variety of binding agents can be implemented with the construction material mixture in accordance with the invention, such as e.g. lime, cement, gypsum, synthetic materials, such as in particular acrylate or polyurea silicates, organic binding agents, water glass, water-soluble adhesives and glues.

Glass-like, i.e. amorphous, water-soluble sodium, potassium and lithium silicates solidified from a melt are referred to as water glass.

Polyurea silicates were developed as two-component injection resins for the mining industry. These organo-mineral systems are based on the reaction of modified polyisocyanates with specifically formulated water glass components and accelerators. The polyurea silicate resins are characterized by improved technical properties vis-à-vis the conventional polyurethanes, aminoplastics and known silicate resins on a polyurethane basis.

Moreover, the construction material according to the invention can comprise up to 50 wt % functional additives.

The construction material mixture according to the invention is characterized by a composite of at least three, preferably four components. The parts of the components are defined by intervals that are defined by an upper and a lower limit.

As an example, the upper limit of the percentage interval for functional additives is 50, 45, 40, 35, 30 or 25 wt (%). The following values are possible, for example, as the lower limit: 0, 3, 6, 10, 13, 16 or 20 wt (%). The disclosure of this application again comprises the set of all intervals that are defined by all possible consistent combinations of the aforementioned upper and lower limits.

Potential functional additives are for instance trass powder, microglass hollow spheres (glass bubbles), aluminium oxide, defoaming agents, magnetite, heavy spar, thickening agents, cellulose, synthetic additives, metallic nanoparticles, in particular silver nanoparticles, fibres or combinations thereof.

When microglass hollow spheres are used as functional additives, the construction material mixture according to the invention can consist both of uncoated as well as of glass spheres coated with an electrically conductive material.

Metallic nanoparticles, such as silver nanoparticles, can be employed in order to impart disinfecting or germicidal properties to the material.

Fibres can be used, for example, for mechanical stabilization, for instance glass fibres, basalt fibres and carbon fibres or synthetic fibres are potential functional additives. It is also possible to use metallic fibres for the modification of electric, magnetic and thermal properties of the construction material mixture.

A potential functional additive is baryte (heavy spar), which can be implemented in particular for the improvement of the shielding properties of the construction material mixture against X-ray radiation.

Further potential functional additives are: sand, gravel, borosilicates, swellable thickeners, associatively acting thickeners, anti-settling agents, bentones, iron oxide and further auxiliary additives that are common for the person skilled in the art.

Aluminium powder can also be added as a functional additive, e.g, the aluminium powder sold by the company GRIMM Metallpulver GmbH, Roth, Germany, under the trademark name “EXPANDIT”. The aluminium acts as an expansion agent. The construction material mixture according to the invention can then contain evenly distributed, tiny aluminium particles. When brought into contact with water, these aluminium particles cause the formation of hydrogen gas in the form of innumerable small bubbles in the mixture. This produces a highly porous foam, which can solidify quickly depending on the binding agent.

For example, by adding swellable thickeners and quick-setting cement such as aluminium casting cement, a stable quick-setting compound is produced, which remains standing in a stable fashion and does not run when printed with a 3D printer. The use of trass powder can influence, i.e. improve, the rigidity of the surface of the layer being formed.

The use of glass bubbles, which are implemented as micropellets, creates in the mixture a kind of hollow space surrounded by the shielding materials such as, for example, graphite, graphene, nanometallic particles and further additives not named here. These “hollow spaces” provide for the absorption, as the radiation is reflected in the layer and the radiation is thus eliminated to the greatest possible extent in the shield (construction material mixture). It is also possible to use other non-conductive additive materials for the formation of the “hollow spaces”. Likewise, hollow spaces can also be created by expanding additives, which also perform this task. By means of synthetic additives, it is possible to prevent adhesion to the substrate. Moreover, the distribution can thus also be regulated.

The construction material mixtures containing fibres can be extruded for instance into strands, which impose a certain preferred direction on the fibres. When the strands are then arranged in a crisscrossed fashion and compressed into panels, a highly stable network is produced from the construction material mixture according to the invention, which bestows upon the thus manufactured panels outstanding mechanical strength values.

The invention also relates to a plaster compound comprising a construction material mixture of the type described above.

The invention differs from standard plaster systems above all by the absorption of electromagnetic radiation in the HF area. The percentage of absorption is greater than 50% as opposed to reflection.

In an advantageous embodiment, it is intended that the processed construction material mixture, applied as a layer with a layer thickness of approx. 1.0 cm, attain an absorption of 40%. An absorption of 72% could be determined with a layer thickness of 2 cm. This excellent absorption performance differs from all plaster systems available on the market.

The invention thus also comprises the advantageous use of a construction material mixture or of a construction material manufactured from the latter as a shielding material predominantly with an absorption of over 50%.

The (dry) construction material mixture is a commercially available and utilized embodiment of the invention, although the described physical properties can only be established in a layer formed from the described construction material mixture.

The invention thus also generally comprises a construction material that is formed at least partially from a construction material mixture as described above.

In a preferred embodiment, it is intended that the construction material contain between 5 and 70 wt (%) of a mixing liquid such as, for instance, water. An interval is indicated for the water part in the construction material, the interval being specified by an upper and a lower limit. For example, the following values are conceivable as the upper limit: 70%, 65%, 60%, 55%, 50%. As the lower limit, for instance, the following values are possible: 5%, 10%, 15%, 20%. The disclosure of this application comprises the set of all intervals defined by all possible consistent combinations of the aforementioned upper and lower limits.

In an advantageous variant, it is intended that the construction material or construction material mixture include in particular one or several functional additives so as to improve the water hydration and thus significantly reduce the water part in the processing of the construction material.

Advantageously, the construction material is supplied ready for processing. In this variant, it is intended that the construction material be maintained with a constant formulation and that, by means of this unvarying formulation, the processing of the construction material with machines, such as, e.g., with mortar injection pumps, can also be carried out reliably. By this means, a constant absorption value continues to be ensured.

It is a further advantage of the invention that the proposed construction material mixture exhibits a high thermal conductivity. A consequence of this high thermal conductivity of the plaster compound is the reduction of the formation of mould in buildings. Mould formation in buildings occurs primarily in room corners, the wall temperature of which is lower than that of the adjacent walls. These differences in temperature (>=3 K) are reduced by the high thermal conductivity of the plaster compound, by which means the formation of mould is also reduced.

The graphite used in the construction material mixture according to the invention significantly increases its electric conductivity. As described above, it continues to possess an increased temperature conductivity. As these surfaces can also be grounded, no electrostatically attractive surfaces are created. Consequently, fogging effects (black dust) can be reduced.

The invention further comprises construction elements, in particular dry construction elements, comprising a construction material mixture of the type described above or such construction elements that can be manufactured using such a construction material mixture. For example, the invention also comprises a construction element such as exterior panels, exterior cladding, ventilation elements with absorption properties greater than 50% and up to 100% for electromagnetic radiation.

Depending on the type of binding agents, auxiliary materials and additive materials used, the invention can be implemented in a great variety of practical areas.

If the construction material mixture according to the invention is processed with a binding agent, such as water glass, and a mesh, panel-shaped construction elements, such as dry construction panels, can be manufactured. The water glass can be provided with a hardener that is designed in such a way that the hardening can be thermally accelerated. Such panels then have advantageous absorption properties for electromagnetic radiation, in particular high-frequency electromagnetic radiation, such as mobile radio radiation and radar. Depending on their configuration, the panels can also be optimized with respect to acoustics, e.g. by acting in an absorbent manner for sound waves. For example, panels containing microglass spheres and water glass as the binding agent are known as so-called “acoustic panels” and are sold e.g. under the name “VeroBoard Acoustic G” by the company Verotec GmbH, Lauingen, Germany (Sto Group).

Two-component polyurea silicate systems, for instance materials such as those manufactured by the company BASF under the name “Masterroc” for grouting in mining, can also be implemented as binding agents. If such Masterroc binding agents (e.g. “MasterRoc MP 367 Foam”) are combined with the construction mixture in accordance with the invention, panels for shielding against electromagnetic radiation can be manufactured that are moreover characterized by a high fire protection. As urea silicates are available as foamable systems, such panels are characterized by a low density so that they are lighter than comparable gypsum fire protection panels.

Such embodiments of the invention can thus be particularly advantageously implemented as fire protection panels in shipbuilding or in aircraft construction. If hollow spheres are used as the loose particles, such panels can also exhibit significant acoustic absorption properties in addition to their significant fire protection properties. Unlike the above-described “VeroBoard” panels with water glass as the binding agent, the panels with urea silicates as the binding agent in accordance with the invention are also water-proof.

By means of a suitable selection of the binding agents, the construction material mixtures according to the invention can also be implemented in airless spraying techniques.

Fire protection agents/acoustic agents are known under the product name “SpreFix”, with which light, non-combustible and acoustically shielding spray coatings can be manufactured. Such materials use a water-based, non-combustible two-component binding agent, which is mixed in a spray nozzle and after being dispensed from the spray nozzle sets within a fraction of a second so that a self-adhesive layer is created already upon impact on walls and ceilings. Such spray agents are used in particular in shipbuilding and on oil platforms as acoustic/fire protection insulation. The insulation then generally also contains glass or mineral fibres. With the construction material mixture according to the invention, such spray insulation systems can also be provided with a suitable shielding function against electromagnetic radiation.

If epoxy or other synthetic resins are used in combination with the construction material mixture in accordance with the invention, the result is high-strength, weatherproof surfaces, which then exhibit a high absorption for electromagnetic radiation. Such systems are then characterized by so-called stealth properties and can be implemented in particular in the military sector for the electronic camouflaging of vehicles, aircraft, containers and other facilities. Such surfaces are then mechanically very resilient. With the construction material mixture according to the invention, moulded foam parts can be manufactured for the manufacture or covering of exterior surfaces of containers, vehicles, aircraft and the like, wherein the insulation is particularly light, non-combustible, weatherproof and absorbent vis-à-vis radar radiation.

The advantageous characteristics of the construction material mixture according to the invention, which can be used in particular as a plaster compound, a casting compound, artificial stone, a construction compound for ventilation ducts, an absorbent 3D-printable construction material mixture and the like, can be summarized as follows:
Graphite-modified plaster compound with a thermal conductivity of λ≥1 W/mK, in particular λ≥3 W/mK.
Excellent shielding insulation for electromagnetic radiation through absorption of over 70% as of a layer thickness of approx. 20 mm; by increasing the layer thickness, an absorption of over 99,999% is possible.
Surface quality levels of Q1-Q2 are attainable; the material can be felted.
The material is machinable and pumpable.
Heat can be generated within the plaster compound by applying an extra-low voltage and electrically conductive poles, so that it can be used as surface heating.
The material can be rendered dimensionally stable, quick-setting, pumpable and printable; walls with a thickness of 60-80 mm could thus be manufactured.
The construction material mixture is very well suited for the application of paints, medium-heavy/heavy wallpaper, tiles and ceramic wall coverings, structural plaster and for the manufacture of surface heating systems; it remains possible to manufacture absorbent ventilation systems with the same; an exchange of air is thus possible, while the penetration of electromagnetic radiation is prevented. This product thus results in new business segments for us in the areas of heating and shielding buildings.
The construction material mixture according to the invention exhibits high shielding insulation, predominantly by absorption, high heat conductivity and high electric conductivity.
In order to obtain the high thermal conductivity and shielding insulation, functional additives are used such as ground natural graphite, expanded graphite, ground film graphite, synthetic graphite, electrically conductive fibres, metallic nanoparticles as individual additives or in combination with each other; the mixing ratio can be adjusted to the respective requirements.
The construction material mixture is preferably used in the form of a dry and wet mixture as a plaster compound for building technology, as a 3D printable compound in the production of construction elements and building structures, and as a casting compound for the manufacture of construction frames. The processing of the construction material mixture is possible both manually as well as by means of plaster and pump/3D printers. The construction material mixture also permits the manufacture of non-load-bearing construction elements such as e.g. exterior cladding panels, face bricks and ventilation constructions. The construction material mixture can also be configured as a latent heat accumulator by addition of phase change materials (PCM).
By means of the binders used in the same, the construction material mixture adheres to almost all substrates.

The invention is explained in more detail below with reference to the attached drawings.

The figures show:

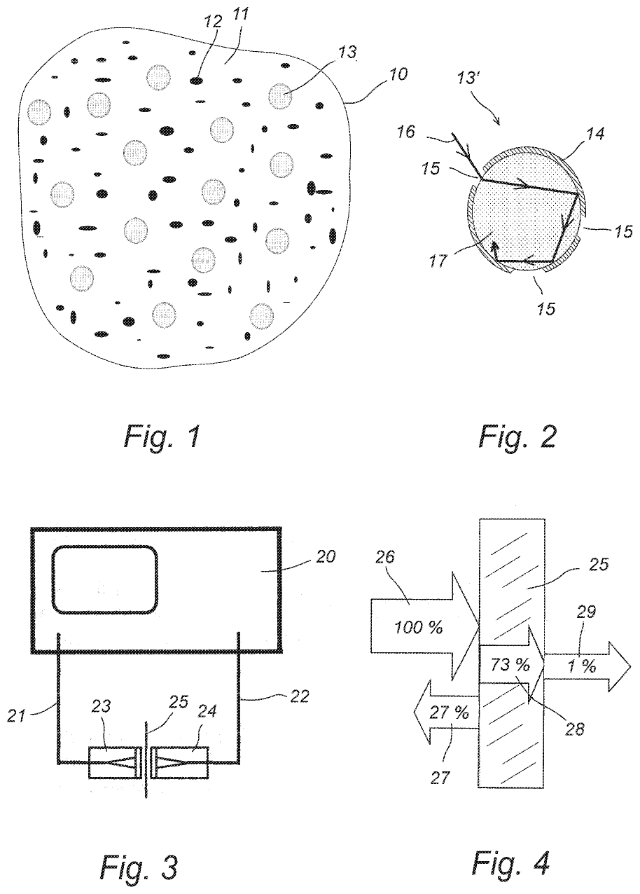

FIG. 1 a schematic representation of a section through a construction element in accordance with the invention;

FIG. 2 a schematic representation of the course of radiation when partly coated glass spheres are used in the construction material mixture in accordance with the invention;

FIG. 3 a schematic representation of measuring equipment for the analysis of the construction elements according to the invention;

FIG. 4 a schematic representation of the absorption characteristics of a construction element made from the construction material mixture according to the invention;

The functional principle of the construction material mixture according to the invention is exemplified in the FIGS. 1 and 2. A construction element 10, which is manufactured from a construction material mixture according to the invention, comprises a binding agent 11, graphite parts 12 in the binding agent and graphite-coated spheres 13. The graphite parts 12 in the binding agent essentially cause a partial reflection of the impinging radiation at the surface and reflections and absorption in the underlying layers. The additional graphite-coated spheres 13 additionally provide for numerous reflections of the radiation, which lengthens the path of the radiation through the construction element 10, which increases the absorbed part of the radiation. The radiation part reflected at the surface of the construction element can be further minimized when the graphite content in the binding agent is not homogeneous, but rather decreases towards the surface of the construction element.

When the graphite-coated spheres 13 are not completely coated with a graphite layer 14, but rather exhibit uncoated areas 15, as shown illustratively on the sphere 13′, a larger portion of the radiation 16 can enter the interior 17 of the partially coated spheres 13′ and effectively “fizzle out” by repeated reflections on the coated adjacent surfaces in the interior 17 of the spheres 13′, which further increases the absorbed part of the radiation.

FIG. 3 depicts a typical test set-up with which the construction material mixtures according to the invention, which were processed into panel-shaped test objects, were analyzed. FIG. 3 shows a vector network analyzer 20 of the type ZVRC from the company Rohde and Schwarz, with which electromagnetic waves in a frequency range of 30 kHz to 8 GHz are generated and can be measured. Line 21, 22 lead or can be led to two coaxial TEM measuring heads 23, 24 between which the test object 25 is arranged (TEM measuring probes for the frequency range 1 MHz-4 GHz from the company Wandel & Goltermann). The generated initial radiation to the test object 25 and the radiation reflected by the test object 25 are measured via the line 21. Via the line 22, the radiation transmitted through the test object 25 is fed to the network analyzer. The absorbed power can then also be determined from the emitted, transmitted and reflected power.

In this measurement, the electric field strengths in the TEM arrangement—as is common with coaxial lines—impinge on the test object in all polarization orientations. One is thus unable to make any discrete statements about the behaviour of the test object in the face of a given linear polarization, yet one gets an impression of how the test object will behave when faced with polarizations of an arbitrary orientation. If a test object shields particularly well in these measurements, it will shield at least correspondingly well vis-à-vis both linear vertical and horizontal polarizations.

Generally, the shielding against electromagnetic waves can occur either by reflection of the waves on a shielding surface and/or by absorption of the power in the shielding material. The shielding part of the reflection depends on the good conductivity of the shielding surface, which can also be described by its surface resistance. The shielding of most materials is based on this principle. If the materials have a very good conductivity, even very thin objects can result in excellent shielding values from 80 dB up to over 100 dB.

The absorption occurs within the shielding material when the latter is “lossy”. Here, the thickness of the material also plays an essential role. It can be determined that all materials that heat up quickly, for instance in a microwave oven, absorb electromagnetic energy in the high-frequency wave range well and are thus also suitable for use in shielding products.

In order to isolate the parts brought about by reflection from those caused by absorption in the characteristics of a test object, it is necessary to conduct, in addition to the transmission (S₂₁), a reflection measurement (S₁₁) with the same measurement set-up in a closed system. If one converts the measured dB values of the transmission and reflection into percentage values, it is possible to use the following equation to represent the power balance:

P_{transmtted}=P_{irradiated}−(P_{reflected}+P_{absorbed})

This means: Of the power (100%) irradiated onto the test specimen, only the part of the power that is not reflected or absorbed makes it through the test specimen (P_{transmitted}).

### Example 1

In a test mixture “GKB 1”, a base of gypsum was used (800 g gypsum anhydrite and 130 g lime, quenched). By adding 500 g ground natural graphite (graphite 99.5) and 120 g graphite-coated glass bubbles (diameter 1-2 mm), 100 g magnetite 10 and functional additives (250 g sand 0.2-1.5 mm, 85 g calcium carbonate, 0.14 g Pangel FF rheology optimizer, 0.03 g Lumiten surfactant, 0.20 g ELOTEX MP2100 redispersible polymer powder) and by adding water, a compound ready for processing was manufactured, which exhibited an excellent adhesion to a vertical Regips surface when applied manually (thrown). A compound approx. 3 cm thick continued to adhere to the wall without sinking. The setting compound could be felted after a waiting period. After setting and drying completely, a 2 cm thick panel was measured in accordance with ASTM D—4935-2010.

The measurement of the shielding effect against electromagnetic waves in the frequency range of 10 MHz to 4.5 GHz and for the determination of the absorption occurred with a device as shown in FIG. 3.

The respective measurement values relating to the test object “GKB1” are depicted in FIG. 4 (at 2450 MHz in the example).

One can see that 100% power was irradiated onto the test object 25 as symbolized by the arrow 26. The measured reflection resulted in a return loss in dB of 5.7 dB.

The resulting power reflection on the front side constituted a reflected power percentage of 27%, which is symbolized by the arrow 27. 73% of the power thus penetrates the test object 25 (arrow 28). As symbolized by the arrow 29, 1% of the power is transmitted. The losses by absorption in the test object thus constitute 73%−1%=72% of the power.

In the case of this test object, a shielding effect of 20 dB was measured. Unlike conventional shielding products, the product in accordance with the invention thus exhibits a particularly high quality, as an essentially greater portion of the power is absorbed rather than reflected or transmitted.

The tested panels have the following measurements 200 mm*200 mm*20 mm. As the shielding effect in the case of absorption occurs within the shielding material, the thickness of the material also plays an essential role. By increasing the layer thickness and modifying the reflection values, the absorption within the shield can be changed, i.e. increased.

### Example 2

In the test mixture “KZ 1”, a base of lime cement was used (800 g white cement, 120 g lime, quenched). By adding 500 g ground natural graphite (graphite 99.5) and 100 g glass bubbles (perlites 0-1 mm), and functional additives (500 g sand 0.2-1.5 mm, 0.2 g Pangel FF rheology optimizer, 0.02 g Lumiten surfactant, 0.4 g ELOTEX MP2100 and 0.5 g ELOTEX FL2280 redispersible polymer powder) and by adding water, a compound ready for processing was manufactured, which exhibited an excellent adhesion to a vertical Rigips surface when applied manually (thrown). A compound approx. 3 cm thick continued to adhere to the wall without sinking. The setting compound could be felted after a waiting period. After setting and drying completely, a 2 cm thick panel was measured in accordance with ASTM D—4935-2010. Here, an absorption of 69.5% could be determined. A further gain in absorption can also attained here by increasing the material thickness. A virtual 100% neutralization of the radiation can also be attained here with a material thickness as of approx. 3 cm. A material thickness of 3 cm was attainable in one production step by means of injection with machine technology.

### Example 3

In the test mixture “AP 2”, a base of lime cement was used (400 g cement, 400 g lime, quenched). By adding 500 g ground natural graphite (graphite 99.5) and 400 g glass bubbles (perlites 0-1 mm) and functional additives (200 g sand 0.2-1.5 mm, 0.02 g Lumiten surfactant, 0.6 g ELOTEX MP2100 and 0.5 g ELOTEX FL2280 redispersible polymer powder) and by adding water, a compound ready for processing was manufactured, which exhibited an excellent adhesion to a vertical Regips surface when applied manually (thrown). A compound approx. 3 cm thick continued to adhere to the wall without sinking. The setting compound could be felted after a waiting period. After setting and drying completely, a 2 cm thick panel was measured in accordance with ASTM D—4935-2010. Here, an absorption of 67.4% could be determined. A further gain in absorption is again attainable by increasing the material thickness so that a virtual 100% neutralization of the radiation could be attained with a material thickness of approx. 3 cm. A material thickness of 3 cm was also attainable here in one production step by means of injection with machine technology.

The conducted measurements are to be regarded as illustrative. It was generally possible to determine that the adhesion of the plaster to other substrates common in construction such as brickwork, artificial stone or porous concrete could be considered very good from a technical point of view.

1-14. (canceled)

15: A construction material mixture, comprising:
a dry mass, comprising the following components
10 to 95 wt. % carbon, and
2 to 70 wt. % binding agent,
1 to 80 wt. % of loose particles,
wherein the wt. % is based on the weight of the dry mass,
wherein a total weight of components in the construction material mixture adds up to 100 wt. %,
wherein the surfaces of the loose particles are at least partially coated with an electrically conductive material, and wherein a coated part of the surfaces of the loose particles is advantageously on average between 50 and 90%.

16: The construction material mixture according to claim 15, wherein the loose particles comprise a glass or a ceramic material.

17: The construction material mixture according to claim 15, wherein the loose particles comprise spheres.

18: The construction material mixture according to claim 15, wherein the size of the loose particles is in a range between 0.01 mm and 10 mm.

19: The construction material mixture according to claim 15, wherein the carbon of the dry mass comprises graphite.

20: The construction material mixture according to claim 15, wherein the electrically conductive material is at least one material selected from the group consisting of magnetite, graphite, and graphene.

21: The construction material mixture according to claim 19, wherein the graphite is present as at least one form selected from the group consisting of a graphite powder, expanded graphite flakes, film graphite, natural graphite, and synthetic graphite.

22: The construction material mixture according to claim 15, wherein the binding agent is at least one element selected from the group consisting of lime, cement, gypsum, synthetic materials, organic binding agents, water glass, water-soluble adhesives, and glues.

23: The construction material mixture according to claim 15, further comprising up to 50 wt. % of a functional additive.

24: The construction material mixture according to claim 23, wherein the functional additive is at least one element selected from the group consisting of trass powder, microglass hollow spheres, aluminum oxide, defoamers, magnetite, heavy spar, thickening agents, cellulose, synthetic additives, metallic nanoparticles, and fibers.

25: A plaster compound, comprising: the construction material mixture in accordance with claim 15.

26: A construction element produced by a process comprising:
manufacturing the construction element from the construction material mixture in accordance with claim 15.

27: The construction material mixture according to claim 17, wherein the loose particles comprise hollow spheres.

28: The construction material mixture according to claim 22, wherein said construction material mixture comprises at least one synthetic material selected from the group consisting of acrylates and polyurea silicates.

29: The construction material mixture according to claim 24, wherein said construction material mixture comprises at least the metallic nanoparticles, wherein the metallic nanoparticles are silver nanoparticles.

30: The construction material mixture according to claim 20, wherein the electrically conductive material is at least the graphite, wherein the graphite is present as at least one form selected from the group consisting of a graphite powder, expanded graphite flakes, film graphite, natural graphite, and synthetic graphite.
